(19) United States
(12) Patent Application Publication
(10) Pub. No.: US 2007/0200589 A1
(43) Pub. Date: Aug. 30, 2007

(54) TEST APPARATUS AND TEST METHOD FOR LIQUID CRYSTAL DISPLAY DEVICE

(75) Inventors: Eun-Woo JEONG, Seoul (KR); Hyun-Min JANG, Seoul (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/559,496

(22) Filed: Nov. 14, 2006

(30) Foreign Application Priority Data
Feb. 15, 2006 (KR) 10-2006-0014788

(51) Int. Cl. G01R 31/00

(52) U.S. Cl. 324/770

(57) ABSTRACT

A test apparatus for a Liquid Crystal Display (LCD) device receives a mode input signal representing whether the LCD device is driven in a normal voltage driving mode or a high voltage driving mode. The test apparatus transmits a voltage to the LCD device and transmits a control signal to a high voltage applying module, which turns on to transmit a high voltage to the LCD device or turns off according to a level of the control signal. The LCD device may remain coupled with the high voltage applying module while the LCD device operation is shifted between a high voltage driving mode and a normal voltage driving mode during a manufacturing process thereof, so manufacturing time for the LCD device may be reduced.

### CROSS REFERENCE TO RELATED APPLICATION

This application claims priority from and the benefit of Korean Patent Application No. 2006-14788, filed on Feb. 15, 2006, which is hereby incorporated by reference for all purposes as if fully set forth herein.

### BACKGROUND OF THE INVENTION

1. Field of the Invention

The present invention relates to a test apparatus and test method, and more particularly, to a test apparatus and a test method for the manufacture of a liquid crystal display (LCD) device.

2. Discussion of the Background

Together with display devices employing cathode ray tubes, LCD devices occupy an important position in the field of image display devices. An LCD device may include two substrates coupled together with a space arranged therebetween, and liquid crystal injected into the space. The LCD device displays a desired image by applying an electric field to the liquid crystals. The electric field controls the orientation of the liquid crystals, thereby controlling the transmittance of light passing through the liquid crystals.

An aging test step, which may be performed during the manufacturing of an LCD device, increases the time required to manufacture the LCD device. In order to reduce the time required to perform the aging test step, another step referred to as High Voltage Stress (HVS) has been introduced. During HVS a high voltage is applied to the LCD device. This voltage is higher than a voltage required for the operation of each component of the LCD device. As a result, the LCD device must withstand an applied voltage with a high level during the manufacturing process.

To perform the HVS, an HVS board is used. Further, during the manufacturing process for the LCD device, the LCD device must be connected to and then disconnected from the HVS board when shifting between the high voltage driving mode of the HVS and a normal voltage driving mode.

### SUMMARY OF THE INVENTION

This invention provides a test apparatus for an LCD device to reduce manufacturing time for the LCD device.

The present invention also provides a test method for the LCD device.

Additional features of the invention will be set forth in the description which follows, and in part will be apparent from the description, or may be learned by practice of the invention.

The present invention discloses a test apparatus for an LCD device includes a controller to receive a supply voltage and a mode signal, to output a data signal and a first voltage to a testing target, and to output a first control signal and a second voltage in response to the mode signal. The LCD device also includes a high voltage applying module coupled with the controller, the high voltage applying module to apply a high voltage to the testing target in response to receiving the first control signal and the second voltage from the controller. Further, the mode signal represents whether the high voltage is to be applied to the testing target.

The present invention also discloses a test method for an LCD device including receiving a mode signal, outputting a data signal and a first voltage to a testing target if the mode signal represents a normal voltage driving mode or a high voltage driving mode, and outputting a first control signal at a first level and a second voltage if the mode signal represents the high voltage driving mode

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 shows a flowchart illustrating a test process for an LCD device according to an exemplary embodiment of the present invention.

FIG. 2 shows a block diagram illustrating an LCD Device and a test apparatus for the LCD Device according to another exemplary embodiment of the present invention.

FIG. 3 shows a block diagram illustrating the LCD Device of FIG. 2 when the LCD Device operates in a normal voltage driving mode.

FIG. 4 shows a block diagram illustrating the LCD Device of FIG. 2 when the LCD Device operates in a high voltage driving mode.

FIG. 5 shows a block diagram illustrating the High Voltage Applying Module of FIG. 2.

FIG. 6 shows a flowchart illustrating a test method for the LCD Device of FIG. 2.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

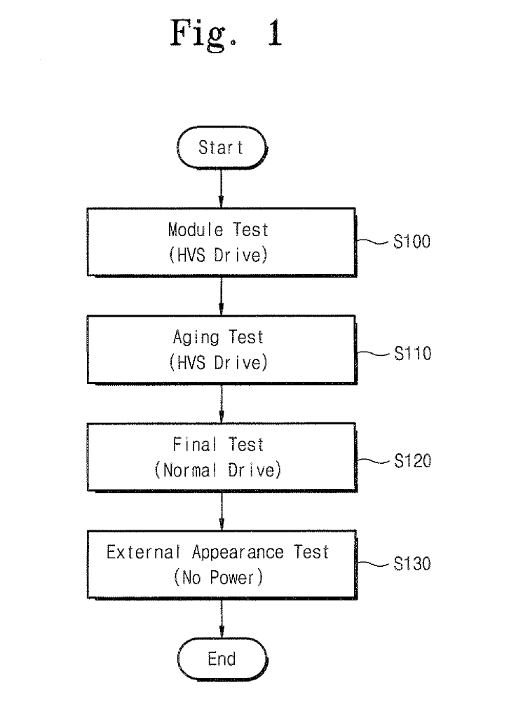

FIG. 1 shows a flowchart illustrating the test process for an LCD device according to an exemplary embodiment of the present invention.

Referring to FIG. 1, an LCD device may be manufactured by a manufacturing process. During the manufacturing process, the LCD device may be assembled through an automated manufacturing process, checked for defects through a test process, and then launched as a finished product. The test process may include a Module Test step S100, an Aging Test step S110, a Final Test step S120, and an External Appearance Test step S130.

The Module Test step S100 may be performed to test basic functions, performance, or operation of the LCD device by connecting the LCD device with a test device through a cable after an automated manufacturing process for the LCD device is complete.

The Aging Test step S110 may be performed to determine whether the LCD device operates properly under severe environmental conditions by operating the LCD device in an environment having a temperature in a range of about 50° C. to about 60° C. higher than a normal operating temperature.

The Module Test step S100 and the Aging Test step S110 may be performed while the LCD device is in the high voltage driving mode and undergoing HVS.

The Final Test step S120 may be performed to inspect performance or operation, such as brightness and flicker, of the LCD device while operating in a normal voltage driving mode, where a normal voltage is applied to the LCD device.

The External Appearance test step S130 may be performed to inspect external surfaces of the LCD device for defects, such as scratches on a liquid crystal panel. The External Appearance test step S130 may be performed on the LCD device while no power is applied to it.

The Module Test step S100 and the Aging Test step S110 may include inspecting the LCD device while in the high voltage driving mode, and the Final Test step S120 may include inspecting the LCD device while in a normal voltage driving mode. Accordingly, the LCD device may be coupled with or decoupled from a high voltage board for the high voltage driving mode when the LCD device is shifted between the high voltage driving mode and the normal voltage driving mode during the manufacturing process.

Coupling the LCD device to the high voltage board or decoupling the LCD device from the high voltage board during the test process may increase the time required to perform all steps in the manufacturing process for the LCD device. For example, connecting the LCD device to or disconnecting the LCD device from the high voltage board through a cable may increase the manufacturing process time for the LCD device. Accordingly, to decrease the manufacturing process time for the LCD device, the LCD device may be coupled to and decoupled from the high voltage board by a switch or an external control signal, instead of a cable.

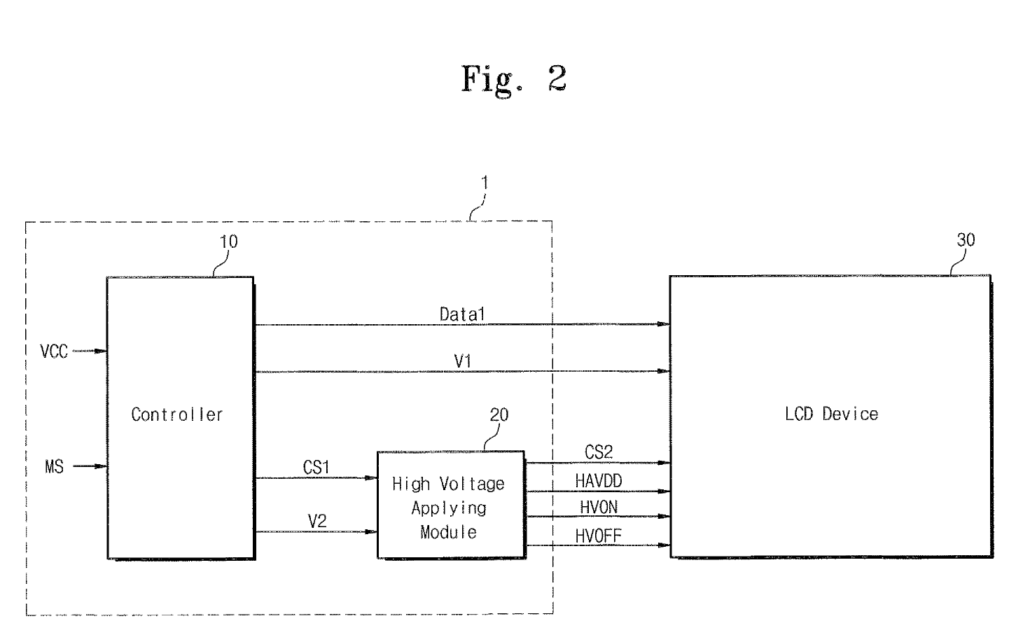

FIG. 2 shows a block diagram illustrating an LCD Device and the test apparatus for the LCD Device according to another exemplary embodiment of the present invention.

Referring to FIG. 2, the test apparatus 1 may be coupled with an LCD Device 30, and may include a Controller 10 and a High Voltage Applying Module 20 to test for failure of the LCD Device 30.

The Controller 10 may operate by receiving a supply voltage VCC and a mode signal MS from an exterior source (not shown). The mode signal MS may represent whether the LCD Device 30 is driven in the normal voltage driving mode or the high voltage driving mode and may be applied in response to an external action, such as the arrangement or position of a switch (not shown). For example, if an activated mode signal MS is applied to the Controller 10, the Controller 10 may determine that a high voltage is to be applied to the LCD Device 30 to drive the LCD Device 30 in a high voltage driving mode. In contrast, if a deactivated mode signal MS is applied to the Controller 10, the Controller 10 may determine that a normal voltage is to be applied to the LCD Device 30 to drive the LCD Device 30 in a normal voltage driving mode.

The Controller 10 may apply a first data signal Data1 and a first voltage V1 to the LCD Device 30 regardless of the state of the mode signal MS applied to the Controller 10. The first data signal Data1 may be an image data signal used to display images on the LCD Device 30. The Controller 10 may be equipped with a computer graphic card, which may include rewriteable storage memory, in order to generate the first data signal Data1. The first voltage V1 may be a reference voltage to operate the LCD Device 30. For example, the first voltage V1 may have a voltage level of about 5 volts. The Controller 10 may apply the first data signal Data1 and the first voltage V1 to the LCD Device 30 regardless of whether the LCD Device 30 is in a normal voltage driving mode or a high voltage driving mode.

The Controller 10 may output a first control signal CS1 and a second voltage V2 to the High Voltage Applying Module 20 in response to the mode signal MS. The first control signal CS1 from the Controller 10 may turn on or turn off the High Voltage Applying Module 20.

For example, if the activated mode signal MS is applied to the Controller 10, the Controller 10 may determine that the high voltage is to be applied to the LCD Device 30 and may output an activated first control signal CS1 to the High Voltage Applying Module 20. Upon receiving the activated first control signal CS1 from the Controller 10, the High Voltage Applying Module 20 may turn on.

The High Voltage Applying Module 20 may be driven in response to the second voltage V2 applied from the Controller 10 together with the activated first control signal CS1. The second voltage V2 applied to the High Voltage Applying Module 20 from the Controller 10 may be a reference voltage to drive the High Voltage Applying Module 20. For example, the second voltage V2 may have a voltage level of about 5 volts.

The high voltage applying module 20 may output a second control signal CS2 and high voltages, such as a power supply voltage HAVDD, a gate-on voltage HVON, and a gate-off voltage HVOFF, to the LCD Device 30 in response to receiving the activated first control signal CS1 and the second voltage V2.

Similarly, if the deactivated mode signal MS is applied to the Controller 10, the Controller 10 may determine that the normal voltage is to be applied to the LCD Device 30 and may output a deactivated first control signal CS1 to the High Voltage Applying Module 20. Upon receiving the deactivated first control signal CS1 from the Controller 10, the High Voltage Applying Module 20 may turn off. The High Voltage Applying Module 20 may not output any signals or high voltages to the LCD Device 30 while turned off. Accordingly, when the High Voltage Applying Module 20 is turned off, the LCD Device 30 may be driven in a normal voltage driving mode in response to receiving the first data signal Data1 and the first voltage V1 applied thereto from the Controller 10.

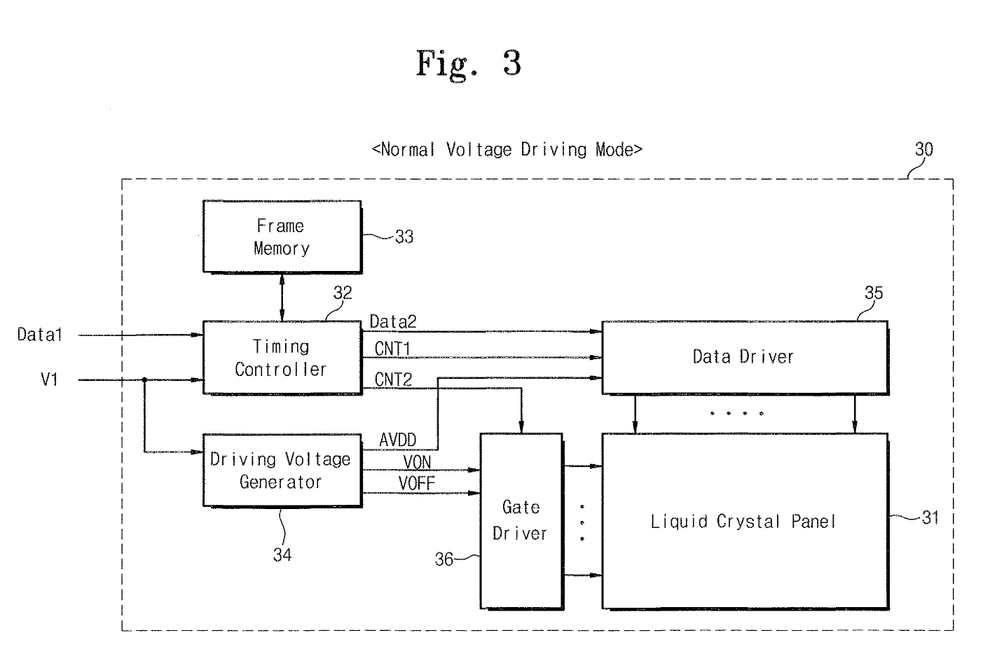

FIG. 3 shows a block diagram illustrating the LCD Device 30 of FIG. 2 when the LCD Device 30 operates in the normal voltage driving mode.

Referring to FIG. 3, the LCD Device 30 may include a Liquid Crystal Panel 31, a Timing Controller 32, a Frame Memory 33, a Driving Voltage Generator 34, a Data Driver 35, and a Gate Driver 36.

The Liquid Crystal Panel 31 may include a first substrate and a second substrate having a common electrode (not shown) and pixel electrodes (not shown), and a liquid crystal (not shown) may be injected between the first substrate and the second substrate. The first substrate having the pixel electrodes may be formed with a plurality of gate lines (not shown) and data lines (not shown), which cross with each other to define a plurality of pixel regions (not shown). In addition, the Liquid Crystal Panel 31 may include a plurality of pixels (not shown) formed in the pixel regions and aligned in a matrix form defined by the data lines and the gate lines.

The Timing Controller 32 may receive the first data signal Data1 and the first voltage V1 from the Controller 10 of the test apparatus 1. The Timing Controller 32 may generate a first driving control signal CNT1, a second driving control signal CNT2, and a second data signal Data2, which have data formats suitable for operating the Liquid Crystal Panel 31. The second data signal Data2 and the first driving control signal CNT1 may be applied to the Data Driver 35, and the second driving control signal CNT2 may be applied to the Gate Driver 36.

The Frame Memory 33 may store frame data of the first data signal Data1 applied from the Controller 10 in order to improve a response speed of the liquid crystals provided in the Liquid Crystal Panel 31.

The Driving Voltage Generator 34 may receive the first voltage V1 from the Controller 10 of the test apparatus to output normal voltages, such as a power supply voltage AVDD, a gate-on voltage VON, and a gate-off voltage VOFF, which allow for operating the LCD Device 30 in a normal voltage driving mode. The power supply voltage AVDD applied to the Data Driver 35 from the Driving Voltage Generator 34 may be a reference voltage applied to the liquid crystals of the Liquid Crystal Panel 31 from the Data Driver 35.

In addition, the gate-on voltage VON, which may be applied to the Gate Driver 36 from the Driving Voltage Generator 34, may turn on a thin film transistor (TFT) in the Liquid Crystal Panel 31. Similarly, the gate-off voltage VOFF, which may be applied to the Gate Driver 36 from the Driving Voltage Generator 34, may turn off a TFT in the Liquid Crystal Panel 31.

The Data Driver 35 may drive the data lines of the Liquid Crystal Panel 31 in response to the second data signal Data2 and the first driving control signal CNT1, which may be applied from the Timing Controller 32, and the power supply voltage AVDD applied from the Driving Voltage Generator 34. The first driving control signal CNT1 applied to the Data Driver 35 from the Timing Controller 32 may include signals such as a horizontal synchronous start signal STH, a latch signal TP, and a data clock signal HCLK (not shown).

The Gate Driver 36 may drive the gate lines of the Liquid Crystal Panel 31 in response to the second driving control signal CNT2 applied from the Timing Controller 32, and in response to the gate-on voltage VON and the gate-off voltage VOFF applied from the Driving Voltage Generator 34. The second driving control signal CNT2 applied to the Gate Driver 36 from the Timing Controller 32 may include signals such as a vertical synchronous start signal STV, a gate clock signal CPV, and an output enable signal OE (not shown).

The LCD Device 30 may operate by using the normal voltages, such as the power supply voltage AVDD, the gate-on voltage VON, and the gate-off voltage VOFF, generated by the Driving Voltage Generator 34 in response to the first voltage V1 applied from the Controller 10 of the test apparatus 1.

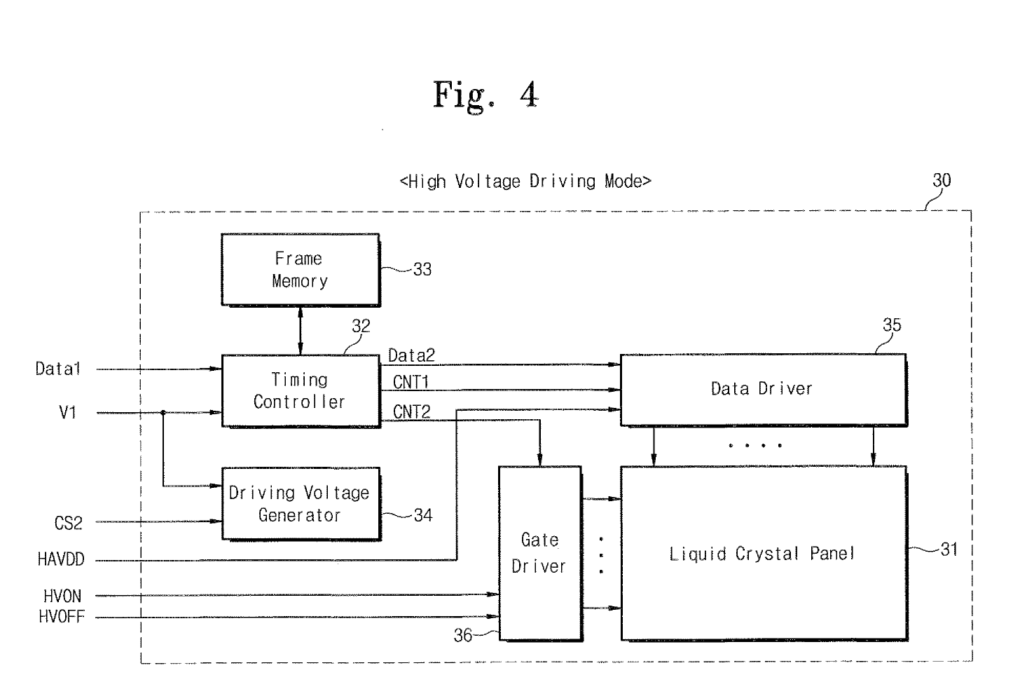

FIG. 4 shows a block diagram illustrating the LCD Device 30 of FIG. 2 when the LCD Device 30 operates in a high voltage driving mode.

Referring to FIG. 4, the LCD Device 30 may have a structure similar to that of the LCD Device 30 shown in FIG. 3, and the same reference numerals denote the same or similar elements. Therefore, detailed descriptions of components performing functions similar to those of components of the LCD Device 30 of FIG. 3 will be omitted.

If the Controller 10 determines that a high voltage is to be applied to the LCD Device 30 in response to receiving the activated mode signal MS, the High Voltage Applying Module 20 is turned on. When the High Voltage Applying Module 20 is turned on, the High Voltage Applying Module 20 may output the second control signal CS2 and the high voltages—power supply voltage HAVDD, a gate-on voltage HVON, and a gate-off voltage HVOFF—to the LCD Device 30.

The second control signal CS2 from the High Voltage Applying Module 20 may be applied to the Driving Voltage Generator 34, thereby turning off the Driving Voltage Generator 34. Accordingly, the Driving Voltage Generator 34 may not output normal voltages, such as the power supply voltage AVDD, the gate-on voltage VON, and the gate-off voltage VOFF, which allow for operating the LCD Device 30 in a normal voltage driving mode.

The High Voltage Applying Module 20 outputs the high voltages, such as the power supply voltage HAVDD, the gate-on voltage HVON, and the gate-off voltage HVOFF, to the LCD Device 30. The power supply voltage HAVDD may be applied to the Data Driver 35, and the gate-on voltage HVON and the gate-off voltage HVOFF may be applied to the Gate Driver 36, to operate the LCD Device 30 in a high voltage driving mode.

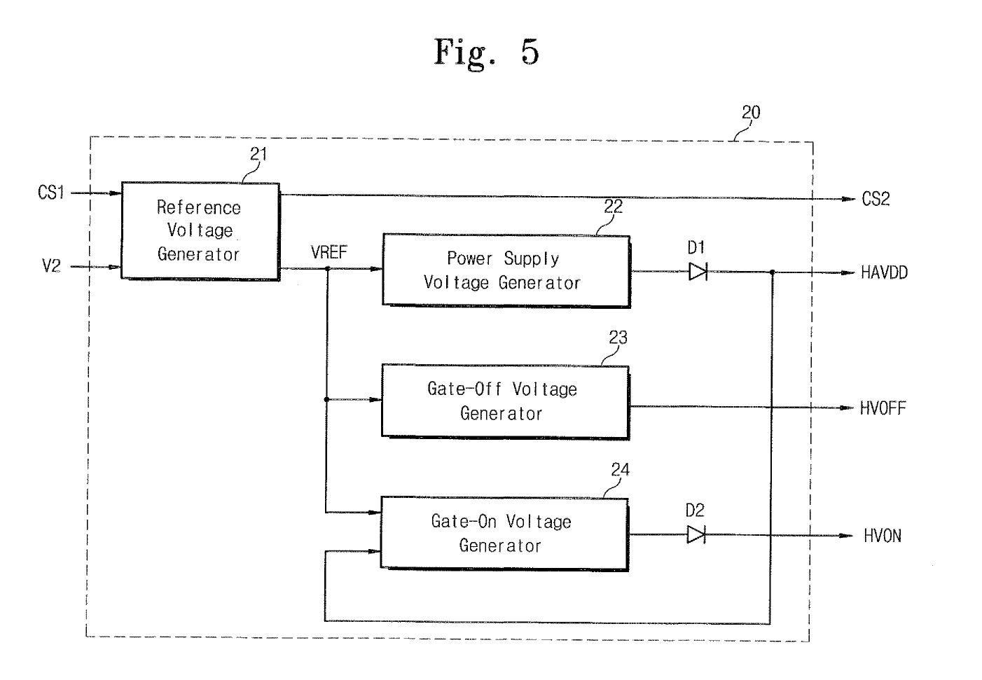

FIG. 5 shows a block diagram illustrating the High Voltage Applying Module 20 of FIG. 2.

Referring to FIG. 5, the High Voltage Applying Module 20 may include a Reference Voltage Generator 21, a Power Supply Voltage Generator 22, a Gate-Off Voltage Generator 23, and a Gate-On Voltage Generator 24.

The Reference Voltage Generator 21 may output the second control signal CS2 and a reference voltage VREF in response to receiving the first control signal CS1 and the second voltage V2 from the Controller 10. The Reference Voltage Generator 21 may generate the reference voltage VREF, which may shift between a voltage level of 0V and a boosted voltage level. The boosted voltage level may be generated by boosting the second voltage V2 received from the Controller 10.

The second control signal CS2 may be applied from the High Voltage Applying Module 20 to the Driving Voltage Generator 34 of the LCD Device 30. Upon receiving the second control signal CS2, the Driving Voltage Generator 34 may turn off.

The Power Supply Voltage Generator 22 may receive the reference voltage VREF from the Reference Voltage Generator 21 and may then generate the power supply voltage HAVDD by rectifying the reference voltage VREF. A first diode D1 may be coupled between the Power Supply Voltage Generator 22 and an output terminal of the High Voltage Applying Module 20 for the power supply voltage HAVDD. If the High Voltage Applying Module 20 is turned off, the LCD Device 30 operates in a normal voltage driving mode and the first diode D1 may block a current flowing from the LCD Device 30 into the High Voltage Applying Module 20.

The Gate-Off Voltage Generator 23 may receive the reference voltage VREF from the Reference Voltage Generator 21 and may then output the gate-off voltage HVOFF after multiplying the reference voltage VREF by a negative value such as negative one (−1) or negative two (−2). The Gate-Off Voltage Generator 23 may include a charge pump circuit (not shown).

The Gate-On Voltage Generator 24 may receive the reference voltage VREF from the Reference Voltage Generator 21 and the power supply voltage HAVDD from the Power Supply Voltage Generator 22, and may then output the gate-on voltage HVON after multiplying the reference voltage VREF by a positive number such as two (2) or three (3). Similar to the Gate-Off Voltage Generator 23, the Gate-On Voltage Generator 24 may also include a charge pump circuit (not shown).

A second diode D2 may be coupled between the Gate-On Voltage Generator 22 and an output terminal of the High Voltage Applying Module 20 for the gate-on voltage HVON. When the High Voltage Applying Module 20 is turned off, the LCD Device 30 operates in a normal voltage driving mode and the second diode D2 may block a current flowing from the LCD Device 30 into the High Voltage Applying Module 20.

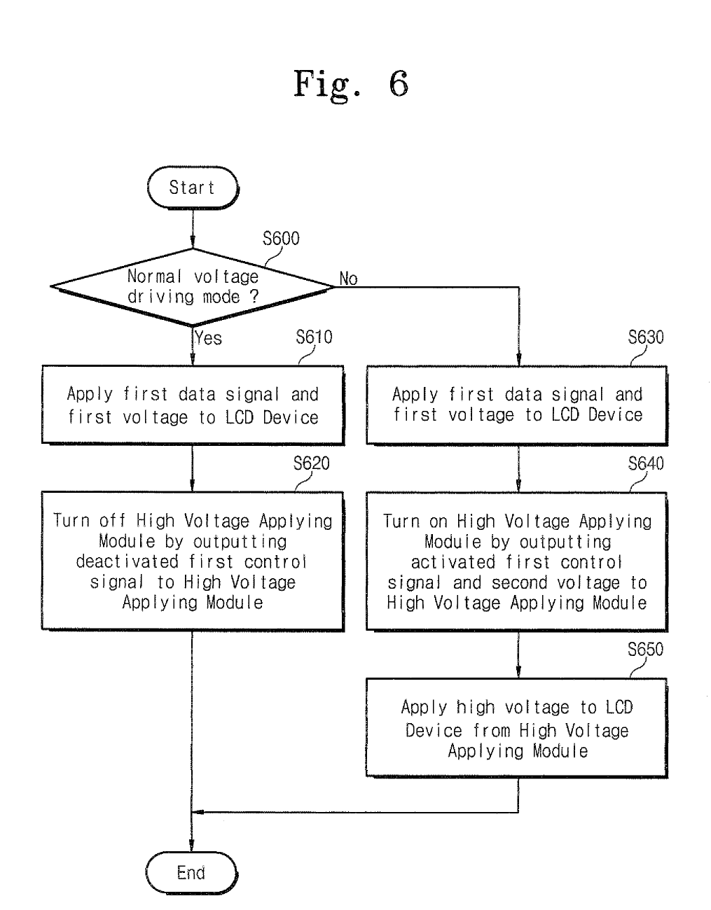

FIG. 6 shows a flowchart illustrating a test method for the LCD Device 30 of FIG. 2.

Referring to FIG. 6, the Controller 10 of the test apparatus 1 determines whether the LCD Device 30 is to be driven in a normal voltage driving mode or a high voltage driving mode based on the mode signal MS applied thereto from an exterior source S600.

If a mode signal MS represents that the LCD Device 30 is to be driven in a normal voltage driving mode, such as where the mode signal MS is deactivated, the Controller 10 applies a normal voltage to the LCD Device 30. Thus, the Controller 10 applies a first data signal Data1 and a first voltage V1 to the LCD Device 30 S610. The Controller 10 also then outputs a deactivated first control signal CS1 to the High Voltage Applying Module 20 to turn off the High Voltage Applying Module 20 S620.

In contrast, if the mode signal MS represents that the LCD Device 30 is to be driven in a high voltage driving mode, such as where the mode signal MS is activated, the Controller 10 applies a high voltage to the LCD Device 30. Thus, the Controller 10 applies the first data signal Data1 and the first voltage V1 to the LCD Device 30 S630. The Controller 10 also outputs an activated first control signal CS1 and a second voltage V2 to the High Voltage Applying Module 20 to turn on the High Voltage Applying Module 20 S640. The High Voltage Applying Module 20 then generates high voltages—power supply voltage HAVDD, a gate-on voltage HVON, and a gate-off voltage HVOFF—to be applied to the LCD Device 30 as the High Voltage Applying Module 20 is turned on S650.

According to the illustrated embodiments of the test apparatus and the test method, the test apparatus for an LCD device may output a control signal to control whether a high voltage is applied to the LCD device in response to a mode signal supplied from an exterior source, and the test apparatus may operate a high voltage applying module according to the control signal. Therefore, an LCD device may undergo testing in a normal voltage driving mode or a high voltage driving mode without coupling to or decoupling from a separate HVS board, and the manufacturing time for the LCD device can be reduced.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A test apparatus, comprising:
a controller receiving a supply voltage and a mode signal, outputting a data signal and a first voltage to a testing target, and outputting a first control signal and a second voltage in response to the mode signal; and
a high voltage applying module applying a high voltage to the testing target in response to receiving the first control signal and the second voltage,
wherein the mode signal represents whether the high voltage is to be applied to the testing target.

2. The test apparatus of claim 1, wherein the testing target comprises a liquid crystal display (LCD) device driven by at least the data signal and the first voltage.

3. The test apparatus of claim 2, wherein the LCD device operates in a high voltage driving mode if the mode signal has a first level, and operates in a normal voltage driving mode if the mode signal has a second level.

4. The test apparatus of claim 3, wherein the controller outputs the first control signal with an activated level if the mode signal has the first level, and outputs the control signal with a deactivated level if the mode signal has the second level.

5. The test apparatus of claim 4, wherein the high voltage applying module is turned on in response to receiving the control signal with an activated level, is turned off in response to receiving the control signal with a deactivated level, and outputs the high voltage to the LCD device when the high voltage applying module is turned on.

6. The test apparatus of claim 5, wherein the high voltage applying module outputs a second control signal to the LCD device when the high voltage applying module is turned on.

7. The test apparatus of claim 6, wherein the LCD device comprises a driving voltage generator to generate a normal voltage to drive the LCD device, and the driving voltage generator is turned off in response to receiving the second control signal.

8. The test apparatus of claim 2, wherein the first voltage is a first reference voltage to operate the LCD device, and the second voltage is a second reference voltage to operate the high voltage applying module.

9. The test apparatus of claim 2, wherein the LCD device is further driven by the high voltage, and the high voltage comprises a power supply voltage, a gate-off voltage, and a gate-on voltage.

10. The test apparatus of claim 9, wherein the high voltage applying module comprises:
a reference voltage generator to generate a reference voltage and a second control signal;
a power supply voltage generator;
a first diode coupled between the power supply voltage generator and the LCD device;
a gate-off voltage generator;
a gate-on voltage generator; and
a second diode coupled between the gate-on voltage generator and the LCD device,
wherein the power supply voltage generator generates the power supply voltage, the gate-off generator generates the gate-off voltage, and the gate-on voltage generator generates the gate-on voltage.

11. A test method, comprising:
receiving a mode signal;
outputting a data signal and a first voltage to a testing target; and
outputting a first control signal at a first level and a second voltage if the mode signal represents the high voltage driving mode.

12. The test method of claim 11, wherein the testing target comprises a liquid crystal display (LCD) device driven by at least the data signal and the first voltage.

13. The test method of claim 12, further comprising:
applying a high voltage to the LCD device if the mode signal represents the high voltage driving mode.

14. The test method of claim 13, wherein the step of applying a high voltage to the LCD device comprises:
turning on a high voltage applying module if the mode signal represents the high voltage driving mode by receiving, at the high voltage applying module, the first control signal at the first level; and
outputting a high voltage from the high voltage applying module.

15. The test method of claim 12, further comprising:
turning off a high voltage applying module if the mode signal represents the normal voltage driving mode.

16. The test method of claim 15, wherein the step of turning off a high voltage applying module comprises:
receiving, at the high voltage applying module, the first control signal at a second level.

17. The test method of claim 11, wherein the first voltage is a first reference voltage to operate a liquid crystal display device, and the second voltage is a second reference voltage to operate a high voltage applying module.

18. The test method of claim 14, wherein the high voltage applied to the LCD device from the high voltage applying module comprises a power supply voltage, a gate-off voltage, and a gate-on voltage.

19. The test method of claim 11, wherein the mode signal represents a normal voltage driving mode or a high voltage driving mode.
